(19) United States
(12) Patent Application Publication
(10) Pub. No.: US 2025/0327835 A1
(43) Pub. Date: Oct. 23, 2025

(54) SIGNAL LOSS PREVENTION TEST SOCKET

(71) Applicant: SAE HAN MICRO TECH CO., LTD., Namyangju-si (KR)

(72) Inventors: Jea Hyoung LEE, Hwaseong-si (KR); Suk Min KIM, Namyangju-si (KR); Jun Cheol PARK, Uijeongbu-si (KR); Hak Jae JOO, Namyangju-si (KR)

(21) Appl. No.: 19/253,952

(22) Filed: Jun. 29, 2025

Related U.S. Application Data
(63) Continuation of application No. PCT/KR2023/019519, filed on Nov. 30, 2023.

(30) Foreign Application Priority Data
Jan. 2, 2023 (KR) 10-2023-0000037

(51) Int. Cl. G01R 1/04

(52) U.S. Cl. CPC G01R 1/0441

(57) ABSTRACT

Provided is a test socket used to measure electrical characteristics of an electric element, and more specifically, provided is a signal loss prevention test socket disposed between opposing terminals so as to electrically connect the terminals. The test socket for preventing signal loss minimizes signal loss. Therefore, inspection speed and accuracy are improved.

### TECHNICAL FIELD

The present disclosure relates to a test socket used for measuring the electrical characteristics of an electrical device.

### BACKGROUND ART

When a semiconductor device is manufactured, the performance testing of the manufactured semiconductor device is required. In the testing of the semiconductor device, a test socket is required to electrically connect a contact pad of a test apparatus to a terminal of the semiconductor device.

Among test sockets, a test socket including an anisotropic conductive sheet having a contact portion in which conductive particles are arranged in the thickness direction of a silicone rubber, and an insulating portion for supporting and insulating adjacent contact portions, has the advantages of allowing flexible connection by absorbing mechanical shock or deformation, and having low manufacturing costs.

FIG. 1 is a view illustrating a test socket according to the related art. The anisotropic conductive sheet 5 of the conventional test socket includes a contact portion 6 in contact with a terminal 2 of a semiconductor device 1, and an insulating portion 8 for supporting and electrically insulating adjacent contact portions 6. An upper end and a lower end of the contact portion 6 are respectively in contact with the terminal 2 of the semiconductor device 1 and a contact pad 4 of a semiconductor test apparatus 3, thereby electrically connecting the terminal 2 and the contact pad 4. The contact portion 6 is formed by hardening a mixture of a silicone resin and fine spherical conductive particles 7, and serves as a conductor through which electricity flows.

However, the insulating portion 8 in the conventional test socket is formed only of an insulating material, so it is not possible to avoid signal interference between the contact portions 6 when transmitting high-frequency signals, thereby degrading the high-frequency signal transmission characteristics.

### RELATED ART DOCUMENTS

(Patent Document 1) Korea Utility Model Publication No. 2009-0006326
(Patent Document 2) Korean Patent Application Publication No. 10-2017-0066981
(Patent Document 3) Korean Patent No. 10-0375117
(Patent Document 4) Korean Patent No. 10-2133675
(Patent Document 5) Korean Patent No. 10-2357723

### DISCLOSURE

### Technical Problem

In order to improve the above-described problem, the present disclosure aims to provide a signal loss prevention test socket with a new structure, which minimizes signal loss and improves testing speed and accuracy.

### Technical Solution

In order to achieve the above-described objective, as a test socket disposed between opposing terminals to electrically connect the terminals, the present disclosure provides a signal loss prevention test socket, which includes a conductive plate having a first surface and a second surface parallel to the first surface, the conductive plate being formed with at least one first through-hole and at least one second through-hole for penetrating the first surface and the second surface, a first insulating film attached to the first surface of the conductive plate in order to prevent the terminals from coming into contact with the first surface of the conductive plate, the first insulating film having first openings formed at positions corresponding to the first through-hole and the second through-hole, a first contact pin electrically connected to the conductive plate, at least a portion of which is in contact with an inner wall of the first through-hole, and both ends of which are in contact with opposing ground terminals, a second contact pin disposed at a distance from an inner wall of the second through-hole in order to be electrically separated or isolated from the conductive plate, both ends of which are in contact with opposing power or signal terminals, and an insulating support portion for supporting the second contact pin and insulating the second contact pin from the conductive plate.

The first contact pin may include a first elastic matrix having a column shape, and a plurality of first conductive particles arranged in a longitudinal direction of the first elastic matrix inside the first elastic matrix.

The second contact pin may include a second elastic matrix having a column shape and a plurality of second conductive particles arranged in a longitudinal direction of the second elastic matrix inside the second elastic matrix.

In addition, the present disclosure may provide the signal loss prevention test socket, characterized in that at least one of both ends of the first contact pin protrudes outward from the conductive plate.

In addition, the signal loss prevention test socket may be provided, characterized in that at least one of both ends of the second contact pin protrudes outward from the conductive plate.

In addition, the signal loss prevention test socket may be provided, characterized in that the first contact pin includes a column portion in which the first conductive particles are arranged along a longitudinal direction of the first contact pin and which is not in contact with the inner wall of the first through-hole, and at least one extension portion in which the first conductive particles are arranged such that one end is connected to an outer surface of the column portion and the other end is in contact with the inner wall of the first through-hole.

In addition, the signal loss prevention test socket may be provided, characterized in that the extension portion is inclined in order to move away from the inner wall of the first through-hole as moving away from the terminal.

In addition, the signal loss prevention test socket may be provided, characterized in that the extension portion is disposed at a center portion of the first contact pin.

In addition, the signal loss prevention test socket may be provided, characterized in that the extension portion is disposed at least one end side of both ends of the first contact pin.

In addition, the signal loss prevention test socket may be provided, characterized in that the conductive plate is non-magnetic.

In addition, the signal loss prevention test socket may be provided, characterized in that the conductive plate is made of copper or a copper alloy.

In addition, the signal loss prevention test socket may be provided, characterized in that the conductive plate includes a plurality of stacked sub-plates.

In addition, the signal loss prevention test socket may be provided, characterized in that the insulating support portion, the first elastic matrix, and the second elastic matrix are made of the same material.

In addition, the signal loss prevention test socket may be provided, characterized in that the insulating support portion, the first elastic matrix, and the second elastic matrix include a silicone-based resin or a polytetrafluoroethylene (PTFE)-based resin.

In addition, the signal loss prevention test socket may be provided, characterized in further including a second insulating film attached to the second surface of the conductive plate in order to prevent the terminals from coming into contact with the second surface of the conductive plate, the second insulating film having second openings formed at positions corresponding to the first through-hole and the second through-hole.

### Advantageous Effects

A signal loss prevention test socket according to the present disclosure minimizes signal losses. Accordingly, testing speed and accuracy are improved.

### DESCRIPTION OF DRAWINGS

FIG. 1 is a view illustrating a test socket according to the related art.

FIG. 2 is a view illustrating a signal loss prevention test socket according to an exemplary embodiment of the present disclosure.

FIGS. 3 and 4 are views illustrating signal loss prevention test sockets according to other exemplary embodiments of the present disclosure.

FIGS. 5 to 7 are views illustrating signal loss prevention test sockets according to still other exemplary embodiments of the present disclosure.

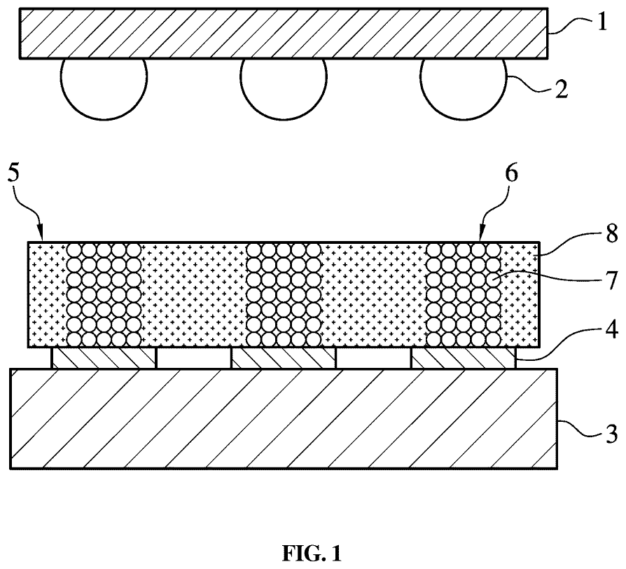

### MODE FOR INVENTION

Hereinafter, preferred exemplary embodiments of the present disclosure will be described in detail with reference to the accompanying drawings. The exemplary embodiment to be described below may be provided as an example in order to sufficiently convey the spirit of the present disclosure to those skilled in the art. Accordingly, the present disclosure may not be limited to the exemplary embodiment to be described below and may be embodied in other forms. In the drawings, the widths, lengths, thicknesses, and the like of components may be exaggerated for convenience of illustration. Throughout the specification, the same reference numerals may refer to the same components.

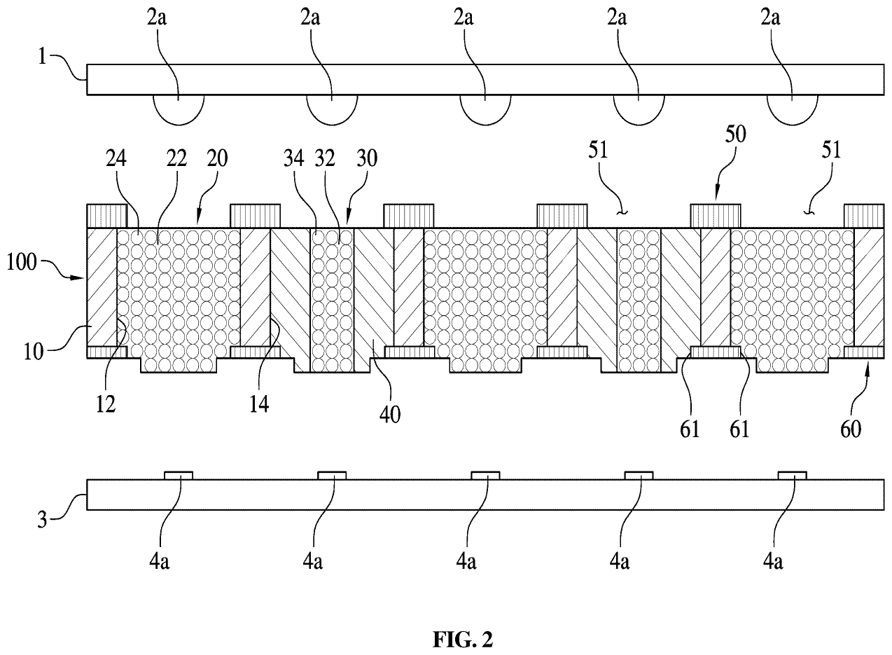

FIG. 2 is a view illustrating a signal loss prevention test socket according to an exemplary embodiment of the present disclosure.

The signal loss prevention test socket 100 may be disposed between opposing terminals and may serve to electrically connect the terminals. For example, the signal loss prevention test socket 100 may serve to electrically connect the terminals 4a, 4b of the test apparatus 3 to the terminals 2a, 2b of the semiconductor device 1.

As shown in FIG. 2, the signal loss prevention test socket 100 according to an exemplary embodiment of the present disclosure may include a conductive plate 10, a plurality of first contact pins 20, a plurality of second contact pins 30, an insulating support portion 40, a first insulating film 50, and a second insulating film 60.

A plurality of first through-holes 12 and a plurality of second through-holes 14 may be formed in the conductive plate 10. In FIG. 2, two first through-holes 12 and two second through-holes 14 are illustrated, but a greater number of first through-holes 12 and second through-holes 14 may be formed.

It may be preferable that the conductive plate 10 is non-magnetic. For example, the conductive plate 10 may be made of copper or a copper alloy.

The conductive plate 10 may be formed as a single plate, or may be formed by stacking a plurality of sub-plates. The first through-holes 12 and the second through-holes 14 may be formed by using a laser or may be formed by using a micro-drill.

Two first contact pins 20 and two second contact pins 30 are illustrated in FIG. 2, but the total number of the first contact pins 20 and the second contact pins 30 may range from several tens to several thousands.

The first contact pin 20 may connect opposing ground terminals 2a, 4a.

Most of the first contact pins 20 may be disposed inside the first through-hole 12. In the present exemplary embodiment, a lower end of the first contact pin 20 shown in the drawing may protrude outward from the conductive plate 10. This may be to reduce the force applied to the first contact pin 20 at the time of measurement. The outer surface of the first contact pin 20 may be in contact with an inner surface of the first through-hole 12. Accordingly, the first contact pin 20 may be electrically connected to the conductive plate 10. All of the first contact pins 20 may be electrically connected through the conductive plate 10. The height of the first contact pin 20 may be equal to or greater than the thickness of the conductive plate 10.

The first contact pin 20 may include a first elastic matrix 22 and a plurality of first conductive particles 24.

The first elastic matrix 22 may be in the shape of a column. For example, it may be in the form of a circular column, or a polygonal column such as a square, hexagonal, or octagonal column. The first elastic matrix 22 may serve to support the first conductive particles 24. In addition, it may serve to bring the first contact pin 20 into close contact with the terminals 2a, 4a while being elastically deformed at the time of measurement and reducing the pressure applied to the terminals 2a, 4a.

The first elastic matrix 22 may be formed of various types of polymer materials. For example, it may be implemented using diene rubbers such as silicone, polybutadiene, polyisoprene, SBR, NBR, and hydrogenated compounds thereof. In addition, it may be implemented using a block copolymer, such as styrene-butadiene block copolymer, styrene-isoprene block copolymer, and the like, and hydrogenated compounds thereof. In addition, it may be implemented using chloroprene, urethane rubber, polyethylene-type rubber, epichlorohydrin rubber, ethylene-propylene copolymer, ethylene-propylenediene copolymer, and the like. In addition, it may be implemented using a polytetrafluoroethylene (PTFE) resin. The first elastic matrix 22 may be preferably implemented using a silicone-based resin or a polytetrafluoroethylene (PTFE) resin.

The first elastic matrix 22 may be obtained by curing a liquid resin.

The first conductive particles 24 may be arranged in the longitudinal direction of the first elastic matrix 22. The first conductive particles 24 may be in contact with each other to provide conductivity in the longitudinal direction of the first contact pin 20. When pressure is applied in the longitudinal direction of the first contact pin 20 for the testing of the semiconductor device 1, the first contact pin 20 may be compressed in the longitudinal direction. Also, as the first conductive particles 24 are closer to one another, the electrical conductivity in the longitudinal direction of the first contact pin 20 may further increase.

In addition, when pressure is applied in the longitudinal direction of the first contact pin 20, the first conductive particles 24 at the center portion of the first contact pin 20 may be pressed toward the inner surface of the first through-hole 12, thereby increasing the contact area between the first contact pin 20 and the inner surface of the first through-hole 12.

The first conductive particles 24 may be implemented with a single electrically conductive metal such as iron, copper, zinc, chromium, nickel, silver, cobalt, or aluminum, or an alloy of two or more of these metals. In addition, the first conductive particles 24 may be implemented by a method of coating the surface of a core metal with a highly conductive metal such as gold, silver, rhodium, palladium, platinum, or silver and gold, silver and rhodium, silver and palladium, and the like.

In order to simplify the manufacturing method, it may be preferable that the first conductive particles 24 are magnetic particles. For example, it may be implemented by coating the surface of a core made of a magnetic metal with a highly conductive metal.

The second contact pin 30 may serve to electrically connect opposing power terminals or signal terminals 2b, 4b. Most of the second contact pin 30 may be disposed inside the second through-hole 14. The lower end of the second contact pin 30 in the drawings may protrude outward from the conductive plate 10. This may be to reduce the force applied to the second contact pin 30 at the time of measurement. The second contact pin 30 may be spaced apart from the inner surface of the second through-hole 14, and may be electrically isolated or separated therefrom. The inner surface of the second through-hole 14 may form a structure similar to a coaxial cable together with the second contact pin 30, and may serve to minimize signal loss of the second contact pin 30 at the time of transmitting high-speed signals. The conductive plate 10 may be connected to the ground terminals 2a, 4a through the first contact pin 20, so the conductive plate 10 may be also in a grounded state. The height of the second contact pin 30 may be equal to or greater than the thickness of the conductive plate 10.

Like the first contact pin 20, the second contact pin 30 may include a second elastic matrix 32 and a plurality of second conductive particles 34.

Like the first elastic matrix 22, the second elastic matrix 32 may be formed of various types of polymer materials. For example, it may be implemented using diene rubbers such as silicone, polybutadiene, polyisoprene, SBR, NBR, and hydrogenated compounds thereof. In addition, it may be implemented using a block copolymer, such as styrene-butadiene block copolymer, styrene-isoprene block copolymer, and the like, and hydrogenated compounds thereof. In addition, it may be implemented using chloroprene, urethane rubber, polyethylene-type rubber, epichlorohydrin rubber, ethylene-propylene copolymer, ethylene-propylenediene copolymer, and the like. In addition, it may be implemented using a polytetrafluoroethylene (PTFE) resin. The second elastic matrix 32 may be preferably implemented using a silicone-based resin or a polytetrafluoroethylene (PTFE) resin. The second elastic matrix 32 may be obtained by curing a liquid resin.

The second elastic matrix 32 may be formed of the same material as the first elastic matrix 22.

The second conductive particles 34 may be arranged in the longitudinal direction of the second elastic matrix 32. The second conductive particles 34 may be in contact with each other to provide conductivity in the longitudinal direction of the second contact pin 30. When pressure is applied in the longitudinal direction of the second contact pin 30 for the testing of the semiconductor device 1, the second contact pin 30 may be compressed in the longitudinal direction. Also, as the second conductive particles 34 are closer to one another, the electrical conductivity in the longitudinal direction of the second contact pin 30 may further increase.

Like the first conductive particles 24, the second conductive particles 34 may be implemented with a single electrically conductive metal such as iron, copper, zinc, chromium, nickel, silver, cobalt, or aluminum, or an alloy of two or more of these metals. In addition, the second conductive particles 34 may be implemented by a method of coating the surface of a core metal with a highly conductive metal such as gold, silver, rhodium, palladium, platinum, or silver and gold, silver and rhodium, silver and palladium, and the like.

In order to simplify the manufacturing method, it may be preferable that the second conductive particles 34 are magnetic particles. For example, it may be implemented by coating the surface of a core made of a magnetic metal with a highly conductive metal.

The insulating support portion 40 may serve to support the second contact pin 30 and insulate the second contact pin 20 from the conductive plate 10.

Like the first elastic matrix 22, the insulating support portion 40 may be formed of various types of polymer materials. For example, it may be implemented using diene rubbers such as silicone, polybutadiene, polyisoprene, SBR, NBR, and hydrogenated compounds thereof. In addition, it may be implemented using a block copolymer, such as styrene-butadiene block copolymer, styrene-isoprene block copolymer, and the like, and hydrogenated compounds thereof. In addition, it may be implemented using chloroprene, urethane rubber, polyethylene-type rubber, epichlorohydrin rubber, ethylene-propylene copolymer, ethylene-propylenediene copolymer, and the like. In addition, it may be implemented using a polytetrafluoroethylene (PTFE) resin. The insulating support portion 40 may be preferably implemented using a silicone-based resin or a polytetrafluoroethylene (PTFE) resin. The insulating support portion 40 may be obtained by curing a liquid resin.

The insulating support portion 40 may be formed of the same material as the first elastic matrix 22 and the second elastic matrix 32.

The first insulating film 50 may serve to prevent the terminals 2a, 2b from contacting the upper surface of the conductive plate 10. The first insulating film 50 may be attached to the upper surface of the conductive plate 10. First openings 51 corresponding to the first through-hole 12 and the second through-hole 14 may be formed in the first insulating film 50. The first insulating film 50 may be, for example, a polyimide film. In order to reliably prevent contact with the upper surface of the conductive plate 10, the first openings 51 may be slightly smaller than the corresponding first through-hole 12 and second through-hole 14. Therefore, not only the upper surface of the conductive plate 10 but also the outer perimeter of the first contact pin 20 may be covered by the first insulating film 50.

The second insulating film 60 may serve to prevent the terminals 4a, 4b from contacting the lower surface of the conductive plate 10. The second insulating film 60 may be attached to the lower surface of the conductive plate 10. Second openings 61 corresponding to the first through-hole 12 and the second through-hole 14 may be formed in the second insulating film 60. The second insulating film 60 may be, for example, a polyimide film. In order to reliably prevent contacting with the lower surface of the conductive plate 10, the second openings 61 may be slightly smaller than the corresponding first through-hole 12 and second through-hole 14. Therefore, not only the upper surface of the conductive plate 10 but also the outer perimeter of the second contact pin 30 may be covered by the second insulating film 60.

Hereinafter, an example of a method for manufacturing the signal loss prevention test socket will be described.

First, the conductive plate 10, in which the first through-hole 12 and the second through-hole 14 are formed, may be disposed inside a mold. It may be preferable that the conductive plate 10 is non-magnetic.

Next, a mixture of liquid resin and magnetic conductive particles may be introduced into the mold. Then, the first through-hole 12 and the second through-hole 14 of the conductive plate 10 may be filled with a mixture of liquid resin and conductive particles. As the mixture continues to be introduced, the mixture may also fill the space surrounded by the side surface of the mold and the upper surface of the conductive plate 10.

Next, magnetic field lines may be passed through the first through-hole 12 and the second through-hole 14 such that conductive particles are concentrated inside the first through-hole 12 and the second through-hole 14. In this case, the magnetic field lines passed through the first through-hole 12 may be controlled such that the conductive particles fully fill the interior of the first through-hole 12 and come into contact with the inner surface of the first through-hole 12.

Also, the magnetic field lines passed through the second through-hole 14 may be controlled such that the conductive particles are concentrated only in the center portion of the second through-hole 14 and move away from the inner surface of the second through-hole 14.

When a non-magnetic material is used as the conductive plate 10, there is an advantage in that the magnetic field line is not distorted by the conductive plate 10 and allows the conductive particles to form a stable contact-pin shape.

Also, the liquid resin may be cured at the same time as the magnetic field line is formed. Then, as shown in FIG. 2, the liquid resin may be cured in a state in which conductive particles are aligned in the first through-hole 12 and the second through-hole 14 in the thickness direction of the signal loss prevention test socket 100.

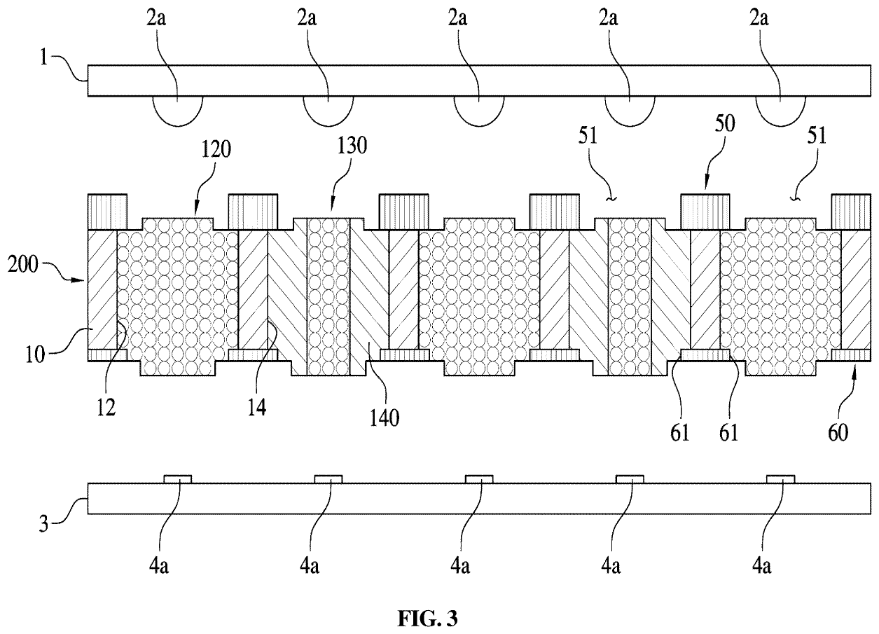

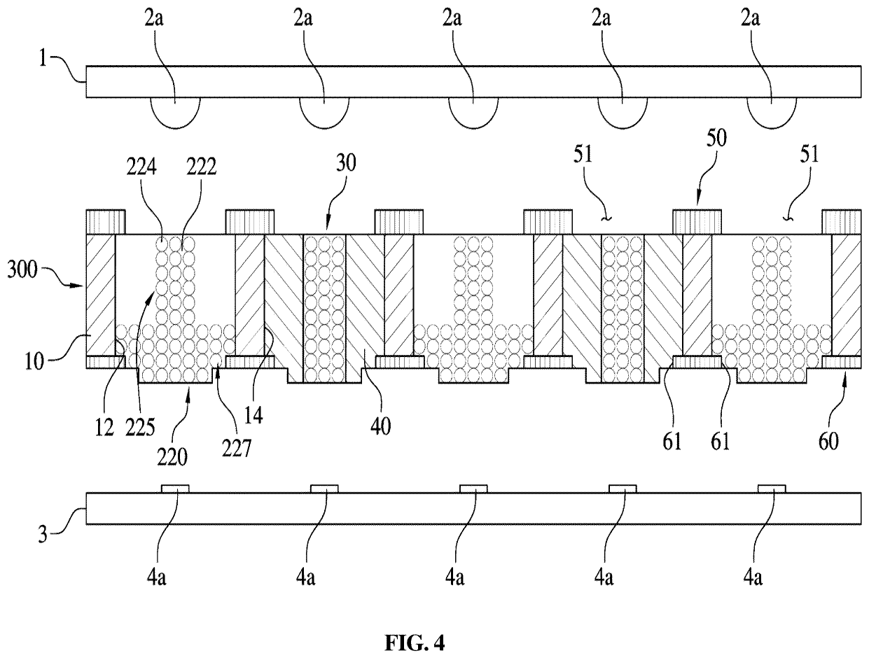

FIGS. 3 and 4 are views illustrating signal loss prevention test sockets according to other exemplary embodiments of the present disclosure.

The signal loss prevention test socket 200 illustrated in FIG. 3 may differ from the exemplary embodiment shown in FIG. 2 in that not only the lower ends but also the upper ends of the first contact pin 120 and the second contact pin 130 in the drawings protrude outward from the conductive plate 10. This may be to reduce the force applied to the first contact pin 120 and the second contact pin 130 at the time of measurement.

The signal loss prevention test socket 200 illustrated in FIG. 4 may differ from the exemplary embodiment illustrated in FIG. 2 in the shape of the first contact pin 220.

As shown in FIG. 4, the first contact pin 220 of the present exemplary embodiment may include a column portion 225 and an extension portion 227.

The column portion 225 may be disposed at a center portion of the first contact pin 220. The first conductive particles 224 of the column portion 225 may be arranged along the longitudinal direction of the first contact pin 220. The column portion 225 may not be in contact with the inner wall of the first through-hole 12.

One end of the extension portion 227 may be connected to the outer surface of the column portion 225. Also, the other end of the extension portion 227 may be in contact with the inner wall of the first through-hole 12. The first conductive particles 224 of the extension portion 227 may be generally arranged along the width direction of the first contact pin 220.

The present exemplary embodiment may have the advantage of preventing excessive pressure from being applied to the first contact pin 220 at the time of measurement. When the pressure applied to the first contact pin 220 increases, the portion of the elastic matrix 222 between the extension portion 227 and the column portion 225 may be deformed, thereby preventing excessive pressure from being imposed on the first contact pin 220. The first conductive particles 224 may not be disposed at the portion of the elastic matrix 222 between the extension portion 227 and the column portion 225, or the density of the first conductive particles 224 may be maintained very low. Therefore, the portion of the elastic matrix 222 between the extension portion 227 and the column portion 225 may serve as a buffer portion.

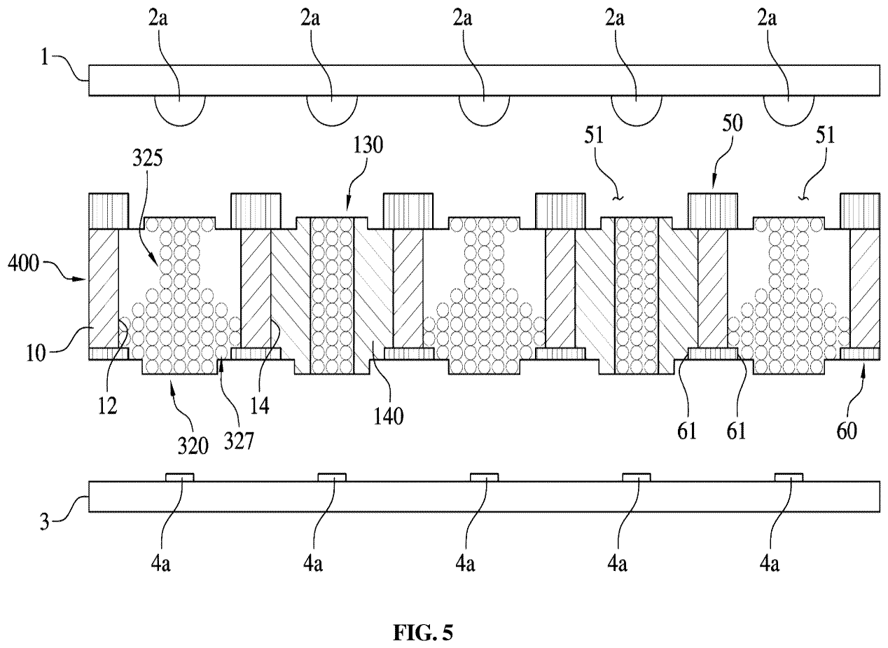

FIGS. 5 to 7 are views illustrating signal loss prevention test sockets according to still other exemplary embodiments of the present disclosure. These exemplary embodiments may differ from the exemplary embodiment illustrated in FIG. 3 in the structure of the first contact pin. Like the exemplary embodiment of FIG. 4, these exemplary embodiments may have the advantage of preventing excessive pressure from being applied to the first contact pin at the time of measurement.

As illustrated in FIG. 5, in the signal loss prevention test socket 400, the column portion 325 of the first contact pin 320 may be disposed at the center portion of the first contact pin 320 in order not to come into contact with the inner wall of the first through-hole 12, and the extension portion 327 may extend from the center portion and the lower portion of the column portion 325. The extension portion 327 may be inclined in order to move away from the inner wall of the first through-hole 12 as moving away from the terminal 4a. The extension portion 327 extending from the center portion of the column portion 325 may not come in contact with the inner wall of the first through-hole 12, and the extension portion 327 extending from the lower portion may come in contact with the inner wall of the first through-hole 12. When the pressure increases, the extension portion 327 extending from the center portion may also come in contact with the inner wall of the first through-hole 12.

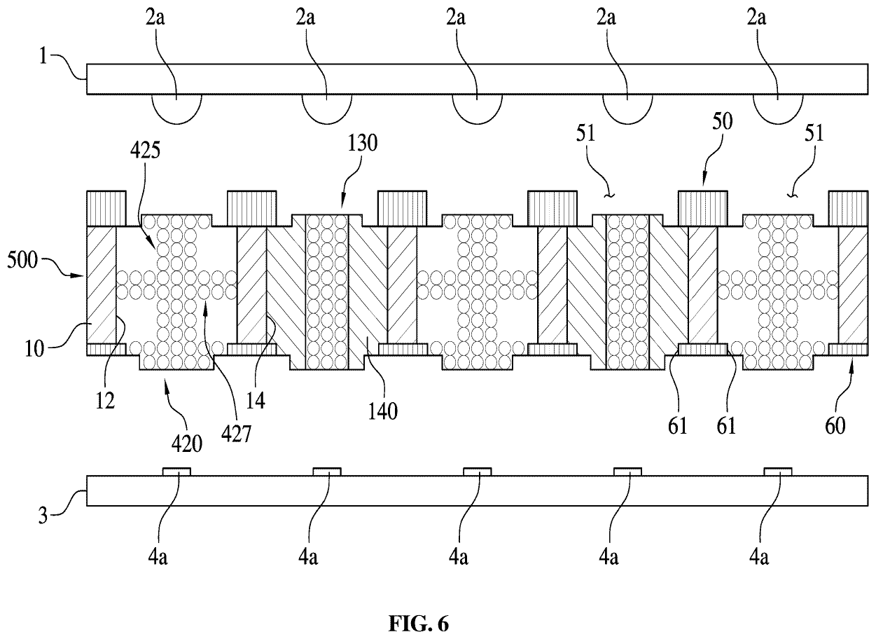

In addition, as illustrated in FIG. 6, in the signal loss prevention test socket 500, the extension portion 427 of the first contact pin 420 may be disposed at the center portion in the longitudinal direction of the first contact pin 420. The extension portion 427 may horizontally extend from the outer surface of the center portion in the longitudinal direction of the column portion 425.

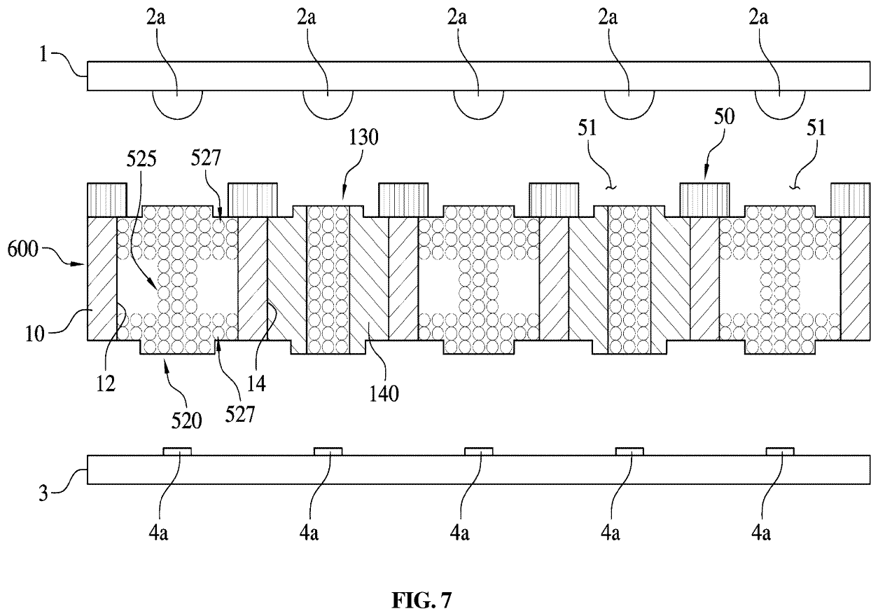

In addition, as illustrated in FIG. 7, in the signal loss prevention test socket 600, the extension portion 527 of the first contact pin 520 may be disposed at both ends of the first contact pin 520. The extension portion 527 may horizontally extend from the outer surface of both ends of the column portion 525. The exemplary embodiment illustrated in FIG. 7 may differ from the exemplary embodiment illustrated in FIG. 3 in that the second insulating film is not included.

The exemplary embodiments described above may be merely illustrative of preferred exemplary embodiments of the present disclosure, and the scope of the present disclosure may not be limited to the described exemplary embodiments, and various changes, modifications, or substitutions may be made by those skilled in the art within the technical spirit of the present disclosure and the claims, and it should be understood that such exemplary embodiments fall within the scope of the present disclosure.

### DESCRIPTION OF REFERENCE NUMERALS

100, 200, 300, 400, 500, 600: signal loss prevention test socket
10, 110: conductive plate
12: first through-hole
14: second through-hole
20, 120, 220, 320, 420, 520, 620: first contact pin
22: first elastic matrix
24: first conductive particle
30: second contact pin
32: second elastic matrix
34: second conductive particle
40, 140: insulating support portion
50: first insulating film
60: second insulating film
10 225, 325, 425, 525, 625: column portion
227, 327, 427, 527, 627: extension portion

1. A signal loss prevention test socket as a test socket disposed between opposing terminals to electrically connect the terminals, the socket comprising:
a conductive plate having a first surface and a second surface parallel to the first surface, the conductive plate being formed with at least one first through-hole and at least one second through-hole for penetrating the first surface and the second surface;
a first insulating film attached to the first surface of the conductive plate in order to prevent the terminals from coming into contact with the first surface of the conductive plate, the first insulating film having first openings formed at positions corresponding to the first through-hole and the second through-hole;
a first contact pin electrically connected to the conductive plate, at least a portion of which is in contact with an inner wall of the first through-hole, and both ends of which are in contact with opposing ground terminals;
a second contact pin disposed at a distance from an inner wall of the second through-hole in order to be electrically isolated from the conductive plate, both ends of which are in contact with opposing power or signal terminals; and
an insulating support portion for supporting the second contact pin and insulating the second contact pin from the conductive plate,
wherein the first contact pin comprises a first elastic matrix having a column shape and a plurality of first conductive particles arranged in a longitudinal direction of the first elastic matrix inside the first elastic matrix, and
the second contact pin comprises a second elastic matrix having a column shape and a plurality of second conductive particles arranged in a longitudinal direction of the second elastic matrix inside the second elastic matrix, and
wherein the first contact pin comprises:
a column portion in which the first conductive particles are arranged along a longitudinal direction of the first contact pin and which is not in contact with the inner wall of the first through-hole; and
at least one extension portion in which the first conductive particles are arranged such that one end is connected to an outer surface of the column portion and the other end is in contact with the inner wall of the first through-hole.

2. The socket of claim 1, wherein at least one of both ends of the first contact pin protrudes outward from the conductive plate.

3. The socket of claim 1, wherein at least one of both ends of the second contact pin protrudes outward from the conductive plate.

4. The socket of claim 1, wherein the extension portion is inclined in order to move away from the inner wall of the first through-hole as moving away from the terminal.

5. The socket of claim 1, wherein the extension portion is disposed at a center portion of the first contact pin.

6. The socket of claim 1, wherein the extension portion is disposed at least one end side of both ends of the first contact pin.

7. The socket of claim 1, wherein the conductive plate is non-magnetic.

8. The socket of claim 7, wherein the conductive plate is made of copper or a copper alloy.

9. The socket of claim 1, wherein the conductive plate comprises a plurality of stacked sub-plates.

10. The socket of claim 1, wherein the insulating support portion, the first elastic matrix, and the second elastic matrix are made of the same material.

11. The socket of claim 10, wherein the insulating support portion, the first elastic matrix, and the second elastic matrix comprise a silicone-based resin or a polytetrafluoroethylene (PTFE)-based resin.

12. The socket of claim 1, further comprising:
a second insulating film attached to the second surface of the conductive plate in order to prevent the terminals from coming into contact with the second surface of the conductive plate, the second insulating film having second openings formed at positions corresponding to the first through-hole and the second through-hole.
